(19) United States
(12) Patent Application Publication
(10) Pub. No.: US 2026/0164580 A1
(43) Pub. Date: Jun. 11, 2026

(54) DISPLAY DEVICE

(71) Applicant: LG Display Co., Ltd., Seoul (KR)

(72) Inventor: Sang-Won KIM, Paju-si (KR)

(73) Assignee: LG Display Co., Ltd., Seoul (KR)

(21) Appl. No.: 19/247,258

(22) Filed: Jun. 24, 2025

(30) Foreign Application Priority Data
Dec. 6, 2024 (KR) 10-2024-0180431

(51) Int. Cl. H05K 5/03; H10K 59/80

(52) U.S. Cl. CPC H05K 5/03; H10K 59/873

(57) ABSTRACT

A display device in some examples can include grooves of different shapes depending on areas on an upper surface of the rear cover that is joined along a rear edge of a cover window. Adhesive strength between the cover window and the rear cover can be maximized. Since a width of the rear cover can be reduced, a width of a bezel corresponding to a non-display area can be reduced.

### CROSS-REFERENCE TO RELATED APPLICATIONS

This application claims priority under 35 35 U.S.C. § 119 (a) to the Korean Patent Application No. 10-2024-0180431, filed in the Republic of Korea on Dec. 6, 2024, the entire contents of which are hereby expressly incorporated by reference into the present application.

### BACKGROUND

### Technical Field

The present disclosure relates to a display device, and more particularly to, a display device with a beneficial adhesive force and narrow bezel.

### Discussion of the Related Art

As large area display devices have been developed, demands for flat display device with small space have been increased. Technologies for a display device including a light emitting diode as one of the flat display device have been developed rapidly. The display device including the light emitting diode can be classified into an organic light emitting display device using organic emitting materials and an inorganic light emitting display device using inorganic luminescent materials.

The light emitting display device includes a display panel for implementing images, and various cover members or plate members disposed on or under the display panel. Those cover members and plate members are joined outside of the display panel to be fabricated to the display device.

The cover members and plate members are joined together in a non-display area outside of the display panel. As the size of the display panel increases, the sizes of the cover members or the plate members joined outside of the display panel can increase. Accordingly, it is necessary and desirable to decrease a bezel area corresponding to the non-display area outside of the display panel. However, as adhesive area between the cover member and the plate member decreases, the adhesive force between the cover member and the plate member decreases. In addition, the adhesive overflows in the course of applying the adhesive, and there is a risk that the adhesives are delaminated from the cover member and/or the plate member due to vibrations or shocks.

### SUMMARY OF THE DISCLOSURE

Accordingly, some embodiments of the present disclosure are directed to a display device that substantially obviates one or more of the problems due to the limitations and disadvantages of the related art.

An aspect of the present disclosure is to provide a display device with beneficial adhesive force among the cover plates and/or plate members joined outside of a display panel.

Another aspect of the present disclosure is to provide a display device with a reduced non-display area to implement a narrow bezel.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, the present disclosure provides a display device that comprises a display panel disposed in a display area on a substrate, a cover window disposed on the display panel, and a rear cover disposed on a rear surface of the display panel and in a non-display area outside of the display panel to accommodate the display panel, wherein an upper surface of the rear cover disposed outside of the display panel is joined along a rear edge of the cover window corresponding to the non-display area, wherein at least one groove onto which an adhesive material is applied is positioned along the upper surface of the rear cover, wherein the at least one groove comprises a first groove positioned in a first area of the upper surface of the rear cover, and a second groove positioned in a second area of the upper surface of the rear cover, and wherein the first groove has a shape different from a shape of the second groove.

According to aspects of the present disclosure, the at least one groove positioned along the upper surface of the rear cover can have a downward protruding cross section.

According to aspects of the present disclosure, the at least one groove positioned along the upper surface of the rear cover can have a wedge-shaped cross section.

According to aspects of the present disclosure, the at least one groove positioned along the upper surface of the rear cover can comprise a first concave portion positioned on the upper surface of the rear cover, and a second concave portion positioned under the first concave portion.

According to aspects of the present disclosure, the first concave portion can have a width larger than a width of the second concave portion.

In another embodiment of the present disclosure, the at least one groove positioned along the upper surface of the rear cover can have a downward sloping cross section.

As an example, the first area of the upper surface of the rear cover can be an area where the adhesive material is linearly applied to the upper surface of the rear cover, and the second area can be an initial application area of the adhesive material to the upper surface of the rear cover, a final application area of the adhesive material to the upper surface of the rear cover, or a corner area of the upper surface of the rear cover.

According to aspects of the present disclosure, the first groove can have a width different from a width of the second groove.

According to aspects of the present disclosure, the first groove can have a width smaller than a width of the second groove.

According to aspects of the present disclosure, the first groove can have a depth different from a depth of the second groove.

According to aspects of the present disclosure, the first groove can have a depth smaller than a depth of the second groove.

According to aspects of the present disclosure, the display device can further comprise a receiving groove having a cross-sectional shape protruding toward an upper surface of the cover window on a rear edge of the cover window corresponding to the upper surface of the rear cover.

According to aspects of the present disclosure, the display device can further comprise a black matrix disposed between the display panel and the cover window.

According to aspects of the present disclosure, the black matrix can be disposed between the rear surface of the cover window adjacent to the receiving groove and the display panel.

According to aspects of the present disclosure, the black matrix can comprise a first black matrix disposed between the display panel and the cover window, and a second black matrix disposed between the first black matrix and the display panel.

According to aspects of the present disclosure, the first black matrix can be disposed between the rear surface of the cover window including the receiving groove and the display panel, and the second black matrix can be disposed between the rear surface of the cover window adjacent to the receiving groove and the display panel.

According to aspects of the present disclosure, the adhesive material can comprise a light shielding material.

According to aspects of the present disclosure, the display panel can further comprise a light emitting diode disposed on the substrate, and a thin film transistor disposed between the substrate and the light emitting diode.

According to aspects of the present disclosure, the light emitting diode can comprise an organic light emitting diode. The display panel can further comprise a heat dissipation sheet and a core plate sequentially disposed between the display panel and the rear cover.

In one or more embodiments of the present disclosure, the grooves with different shapes depending on area are positioned on the upper surface of the rear cover joined to the rear edge of the cover window. As the application area of the adhesive material between the rear surface of the cover window and the rear cover increases, adhesive force between the cover window and the rear cover can be maximized.

According to aspects of the present disclosure, it is possible to secure beneficial adhesive force between the rear cover and the cover window while the rear cover has a narrow width. Accordingly, the bezel area corresponding to the non-display area can be reduced significantly so that it is possible to implement narrow bezel.

Alternatively, according to aspects of the present disclosure, the receiving groove in which the adhesive material can be entered is equipped on the rear edge of the cover window. As the adhesive force between the cover window and the rear cover further increases, it is possible to fabricate a display device that can implement stable modulation, and thereby, implementing display device with further beneficial durability.

It is to be understood that both the foregoing general description and the following detailed description are example and explanatory, and are intended to provide further explanation of the inventive concepts as claimed.

### BRIEF DESCRIPTION OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates a schematic exploded perspective view of a display device that can be applied to various embodiments of the present disclosure.

FIG. 2 illustrates a schematic circuit diagram of the display panel in accordance with one or more embodiments of the present disclosure.

FIG. 3 illustrates a schematic cross-sectional view of a display panel with a light emitting diode constituting a display device that can be applied to various embodiments of the present disclosure.

FIG. 4 illustrates a schematic cross-sectional view of a display device in accordance with various first embodiments of the present disclosure.

FIG. 5 illustrates a cross-sectional view enlarging “A” portion in FIG. 4.

FIG. 6 illustrates a schematic plain view of a rear cover that can be applied to various embodiments of the present disclosure.

FIG. 7 illustrates a schematic cross-sectional view of the rear cover taken along a line VII-VII′ in FIG. 6.

FIG. 8 illustrates a schematic cross-sectional view of the rear cover taken along a line VIII-VIII′ in FIG. 6.

FIGS. 9 to 12 illustrate a schematic cross-sectional view of a rear cover that can be applied to various embodiments of the present disclosure.

FIG. 13 illustrates a schematic cross-section view of a display device in accordance with a second embodiment of the present disclosure.

FIG. 14 illustrates a cross-sectional view enlarging “B” portion in FIG. 13.

FIG. 15 is a schematic cross-sectional view where adhesive material is applied or positioned between the rear cover and the cover window in the display device in accordance with the second embodiment of the present disclosure.

FIG. 16 is a schematic cross-sectional view where adhesive material is applied or positioned between the rear cover and the cover window in the display device in accordance with a third embodiment of the present disclosure.

FIG. 17 is a graph illustrating pull test result of an adhesive applied between the rear cover without the groove and the cover window.

FIG. 18 is a graph illustrating pull test result of an adhesive applied between the rear cover with the groove and the cover window.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art can unnecessarily obscure the gist of the present disclosure, the detailed description thereof can be omitted herein or can be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified.

In analyzing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included. Further, the term “can” fully encompasses all the meanings and coverages of the term “may” and vice versa.

Although the terms first, second, and the like can be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display device according to all embodiments of the present disclosure are operatively coupled and configured.

Reference will now be made in detail to aspects of the disclosure, examples of which are illustrated in the accompanying drawings. Wherever possible, the same reference numbers will be used throughout the drawings to refer to the same or like parts.

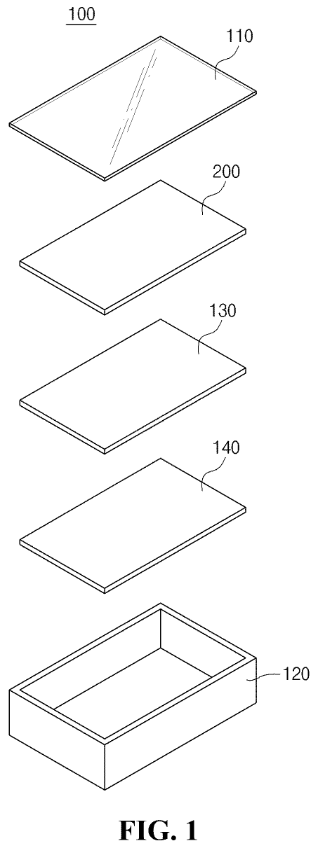

FIG. 1 illustrates a schematic exploded perspective view of a display device that can be applied to various embodiments of the present disclosure.

Referring to FIG. 1, a display device 100 in accordance with the present disclosure can comprise a cover window or a cover glass 110, a rear cover or a bottom frame 120 disposed facing the cover window, a heat dissipation sheet or a heat dissipation plate 130 and a core plate 140 sequentially disposed between the cover window 110 and the rear cover 120, and a display panel 200 disposed between the cover window 110 and the heat dissipation sheet 130.

The cover window 110 constitutes an outer periphery or edge of the display device 100. The cover window 110 is located outside of the display panel 200 where images are displayed. The cover window 110 where the images of the display panel 200 are transmitted protects the display panel 200 from outer shocks or stresses.

The cover window 110 can comprise tempered glass and/or tempered plastics and the likes. For example, the cover window can comprise, but is not limited to, high strength tempered glass, acrylic resins and/or (meth)acrylate resins such as polyethylene terephthalate (PET) and/or polymethyl methacrylate (PMMA) to prevent outer scratches. The cover window 110 can be fabricated by injection mold with an in mold lamination method or a co-extrusion method using those materials. If flexible properties are required, the cover window 110 can be manufactured from a plastic material.

The rear cover 120 can be a cover bottom and/or a plate bottom. The rear cover 120 disposed under the heat dissipation sheet 130 and/or the core plate 140 includes an inner space so that the rear cover 120 can accommodate the display panel 200, the heat dissipation sheet 130 and/or the core plate 140. Alternatively, the rear cover 120 can enclose or surround at least a portion of the outside of the display panel 200, the heat dissipation sheet 130 and/or the core plate 140.

In one embodiment, the rear cover 120 can comprise metal materials. In another embodiment, the rear cover 120 can comprise fibers to improve rigidity. As an example, the rear cover 120 can comprise, but is not limited to, at least one of glass fiber, carbon fiber, metallic wire, and metallic fiber.

The heat dissipation sheet 130 can be disposed under the display panel 200. The heat dissipation sheet 130 can have a size or a dimension smaller than a size or a dimension of the display panel 200. The heat dissipation sheet 130 can be joined to a rear surface of the display panel 200 using a double-sided adhesive tape, a foam tape and the likes. In another embodiment, the heat dissipation sheet 130 can comprise ferromagnetic materials and/or paramagnetic materials.

In this case, the heat dissipation sheet 130 can provide rigidity to the display panel 200. The heat dissipation sheet 130 can release heat generated in the display panel 200 to the outside.

In another embodiment, the heat dissipation sheet 130 can have high heat dissipation property and can include metallic material. For example, the heat dissipation sheet 130 can comprise aluminum and/or aluminum alloys. In another embodiment, the heat dissipation sheet 130 can comprise at least one of copper (Cu), silver (Ag), iron (Fe), nickel (Ni) and tungsten (W), or can be formed of a heat-dissipating metal plate whose outer surface is plated with at least one of nickel (Ni), silver (Ag) and gold (Au).

The core plate 140 is disposed on the rear surface of the display panel 200 to support the display panel 200. As an example, the core plate 140 can comprise, but is not limited to, metallic material. The core plate 140 can be engaged to the rear cover 120 by mechanical bonding means such as a screw, but is not limited thereto.

The display panel 200 can be modularized with its edges surrounded by the rear cover 120, and the cover window 110 is disposed on the display panel 200. The display panel 200 can comprise a substrate, a light emitting diode, and optionally, a color filter layer and/or a thin film transistor. The display panel 200 constituting the display device 100 is described in more detail.

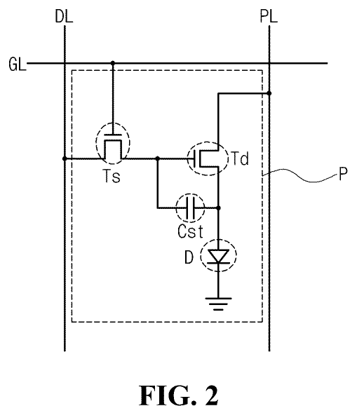

FIG. 2 illustrates a schematic circuit diagram of the display panel 200 constituting the display device 100 in accordance with one or more embodiments of the present disclosure.

Referring to FIG. 2, a gate line GL, a data line DL and power line PL, each of which crosses each other to define a pixel region P, are provided in the display panel 200. A switching thin film transistor Ts, a driving thin film transistor Td, a storage capacitor Cst and a light emitting diode D are disposed within the pixel region P. The pixel region P can comprise a red (R) pixel, a green (G) pixel and/or a blue (B) pixel. However, embodiments of the present disclosure are not limited to such examples. The display device 100 can comprise a plurality of such pixel regions P which can be arranged in a matrix configuration or other configurations.

The switching thin film transistor Ts is connected to the gate line GL and the data line DL. The driving thin film transistor Td and the storage capacitor Cst are connected between the switching thin film transistor Ts and the power line PL. The light emitting diode D is connected to the driving thin film transistor Td.

When the switching thin film transistor Ts is turned on by a gate signal applied to the gate line GL in the display device 100 or the display panel 200, a data signal applied to the data line DL is applied to a gate electrode of the driving thin film transistor Td and one electrode of the storage capacitor Cst through the switching thin film transistor Ts.

The driving thin film transistor Td is turned on by the data signal applied to a gate electrode so that a current proportional to the data signal is supplied from the power line PL to the light emitting diode D through the driving thin film transistor Td. And then, the light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the light emitting display device can display a desired image.

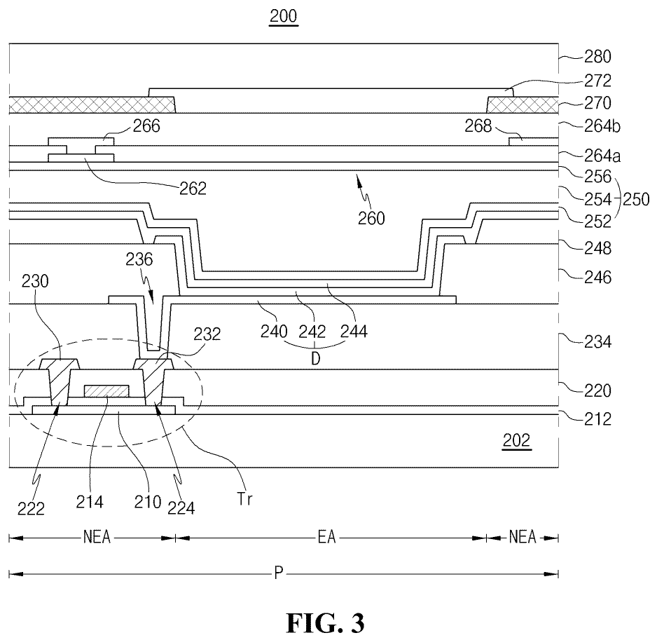

FIG. 3 illustrates a schematic cross-sectional view of the display panel 200 constituting the display device that can be applied to various embodiments of the present disclosure. The pixel circuit configuration of FIG. 2 can be used in the display device of FIG. 3 or other figures of the present application.

Referring to FIG. 3, the display panel 200 comprises a substrate 202, a light emitting diode D disposed on the substrate 200, and optionally, a thin film transistor Tr disposed on the substrate 202, a color filter layer 272 and/or a black matrix 270 disposed on the light emitting diode D.

The pixel region P including the red (R) pixel, the green (G) pixel and the blue (B) pixel can be defined in the substrate 202. Optionally, the pixel region P can comprise a white (W) pixel. The substrate 202 can be a glass substrate and/or a flexible substrate. For example, the substrate 202 can be one of, but is not limited to, a polyimide (PI) substrate, a polyethersulfone (PS) substrate, a polyethylenenaphthalate (PEN) substrate, a polyethylene terephthalate (PET) substrate, a polycarbonate (PC) substrate and a fiber reinforced plastic (FRP) substrate.

The thin film transistor Tris disposed on the substrate 202. In FIG. 3, the thin film transistor Tr is disposed directly on the substrate 202. Alternatively, a buffer layer is disposed on the substrate 202, and the thin film transistor Tr can be disposed on the buffer layer. For example, the buffer layer can comprise, but is not limited to, inorganic insulating material such as silicon oxide (SiOₓ, wherein 0<x≤2), silicon nitride (SiNₓ, wherein 0<x≤2), and the likes.

The thin film transistor Tr can comprise a semiconductor layer 210, a gate electrode 214, a source electrode 230 and a drain electrode 232. The thin film transistor Tr can be a driving thin film transistor Td (FIG. 2).

The semiconductor layer 210 is disposed on the substrate 202. In one embodiment, the semiconductor layer 210 can comprise, but is not limited to, oxide semiconductor materials. In this case, a light-shield pattern can be disposed under the semiconductor layer 210. The light-shield pattern can prevent light from being incident toward the semiconductor layer 210, and thereby, preventing or reducing the semiconductor layer 210 from being degraded by the light. Alternatively, the semiconductor layer 210 can comprise polycrystalline silicon. In this case, opposite edges of the semiconductor layer 210 can be doped with impurities.

A gate insulating layer 212 comprising an insulating material is disposed on the semiconductor layer 210 on the whole substrate 202. The gate insulating layer 212 can comprise, but is not limited to, an inorganic insulating material such as silicon oxide (SiOₓ, wherein 0<x≤2) or silicon nitride (SiNₓ, wherein 0<x≤2).

The gate electrode 214 made of a conductive material such as a metal is disposed on the gate insulating layer 212 so as to correspond to a center of the semiconductor layer 210. For example, the gate electrode 214 can comprise, but is not limited to, metal such as copper (Cu), molybdenum (Mo), titanium (Ti), aluminum (Al), gold (Au) and/or silver (Au). The gate electrode 214 can have a single-layer structure or a multiple-layer structure.

While the gate insulating layer 212 is disposed on the entire area of the substrate 202 as shown in FIG. 3, the gate insulating layer 212 can be patterned identically as the gate electrode 214.

An interlayer insulating layer 220 comprising an insulating material is disposed on the gate electrode 214 and covers an entire surface of the substrate 202. For example, the interlayer insulating layer 220 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryls. The interlayer insulating layer 220 can have a single-layer structure or a multi-layer structure.

The interlayer insulating layer 220 has first and second semiconductor layer contact holes 222 and 224 that expose or do not cover a portion of the surface nearer to the opposing ends than to a center of the semiconductor layer 210. The first and second semiconductor layer contact holes 222 and 224 are disposed on opposite sides of the gate electrode 214 and spaced apart from the gate electrode 130. The first and second semiconductor layer contact holes 222 and 224 are formed within the gate insulating layer 212 and the interlayer insulating layer 220 in FIG. 3. Alternatively, in certain embodiments, the first and second semiconductor layer contact holes 222 and 224 can be formed only within the interlayer insulating layer 220 when the gate insulating layer 212 is patterned identically as the gate electrode 214.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can comprise amorphous silicon.

A passivation layer 234 is disposed on the source electrode 230 and the drain electrode 232. The passivation layer 234 covers the thin film transistor Tr on the entire substrate 202. The passivation layer 234 has a flat top surface and a drain contact hole (or a contact hole) 236 that exposes or does not cover the drain electrode 154 of the thin film transistor Tr. For example, the passivation layer 234 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The light emitting diode D is disposed on the passivation layer 234. The light emitting diode D comprises a first electrode 240 that is disposed on the passivation layer 234 and connected to the drain electrode 232 of the thin film transistor Tr. The light emitting diode D further comprises an emissive layer 242 and a second electrode 244 each of which is disposed sequentially on the first electrode 240. The light emitting diode D can be disposed in each of the red (R) pixel, the green (G) pixel and the blue (B) pixel, and can emit red color light, green color light and blue color light, respectively.

One of the first electrode 240 and the second electrode 244 can be an anode, and the other of the first electrode 240 and the second electrode 244 can be a cathode. One of the first electrode 240 and the second electrode 244 can be a reflective electrode, and the other of the first electrode 240 and the second electrode 244 can be a transmissive electrode.

The first electrode 210 is disposed separately in each pixel region P. In one embodiment, the first electrode 210 can be an anode and comprise conductive material having relatively high work function value, for example, a transparent conductive oxide (TCO). For example, the first electrode 240 can comprise, but is not limited to, indium-tin-oxide (ITO), indium-zinc-oxide (IZO), indium-tin-zinc-oxide (ITZO), tin oxide (SnO), zinc oxide (ZnO), indium-copper-oxide (ICO) and aluminum:zinc oxide (Al:ZnO; AZO).

The first electrode 240 can have a single-layer structure of the transparent conductive oxide. Alternatively, the first electrode 240 can further comprise a reflective layer so that the first electrode 240 can have a double-layer or a triple-layer structure. The first electrode 240 can be a reflective electrode.

For example, the reflective layer can comprise, but is not limited to, silver (Ag) or an alloy of silver (Ag), and at least one of palladium (Pd), copper (Cu), indium (In) and neodymium (Nd), aluminum-palladium-copper (APC) alloy. As an example, the first electrode 240 can have a double-layer structure of Ag/ITO or APC/ITO, or a triple-layer structure of ITO/Ag/ITO or ITO/APC/ITO.

In addition, a bank layer 246 is disposed on the passivation layer 234 in order to cover edges of the first electrode 240. The bank layer 246 exposes or does not cover a center of the first electrode 240 corresponding to the pixel region P. A spacer 248 can be disposed on the bank layer 246. The bank layer 246 and the spacer 248 can comprise the same material. For example, each of the bank layer 246 and the spacer 248 can comprise a light-shielding or light-absorbing material.

An emissive layer 242 is disposed on the first electrode 240. In one embodiment, the emissive layer 242 can have a single-layer structure of an emitting material layer (EML). The EML can comprise organic emitting materials or inorganic luminescent materials. The display device 200 of the present disclosure can comprise, but is not limited to, an organic light emitting display device or an inorganic light emitting display device.

In the organic light emitting display device, the EML can comprise a host and a dopant as an emitter. In the red (R) pixel, the EML can comprise a red host and a red dopant. In the green (G) pixel, the EML can comprise a green host and a green dopant. In the blue (B) pixel, the EML can comprise a blue host and a blue dopant. In the inorganic light emitting display device, the EML can comprise luminescent particles such as quantum dots (QDs) and quantum rods (QRs)

In another embodiment, the emissive layer 242 can have a multiple-layer structure. For example, the emissive layer 242 can further comprise at least one of a hole injection layer (HIL), a hole transport layer (HTL), an electron blocking layer (EBL) disposed sequentially between the first electrode 242 and the EML, and/or a hole blocking layer (HBL), an electron transport layer (ETL), an electron injection layer (EIL) disposed between the EML and the second electrode 244.

In one embodiment, the light emitting diode D can emit white color in each of the red (R) pixel, the green (G) pixel and the blue (B) pixel. In this case, the emissive layer 242 can be disposed in plural pixel regions Ps. For example, the emissive layer 242 of the light emitting diode D can comprise a first emitting part including a first emitting material layer, a second emitting part including a second emitting material layer and a charge generation layer (CGL) disposed between the first emitting part and the second emitting part so that the emissive layer 242 can have a double-stack structure. In this case, one of the first emitting material layer and the second emitting material layer can be a blue emitting material layer, and the other of the first emitting material layer and the second emitting material layer can be a yellow-green emitting material layer, or can comprise a red emitting material layer and a green emitting material layer.

In another embodiment, the emissive layer 242 of the light emitting diode D can further comprise a third emitting part including a third emitting material layer and a second charge generation layer disposed between the second emitting part and the third emitting part so that the emissive layer 242 can have a triple-stack structure. In this case, the third emitting material layer can be a blue emitting material layer.

The second electrode 244 is disposed on the substrate 202 above which the emissive layer 242 is disposed. The second electrode 244 can be disposed on an emission area EA. The second electrode 244 can comprise a conductive material with a relatively low work function value compared to the first electrode 240 so that the second electrode 244 can act as a cathode. For example, the second electrode 244 can comprise, but is not limited to, aluminum (Al), magnesium (Mg), calcium (Ca), silver (Ag), and/or alloys thereof, for example, magnesium-silver alloy (Mg:Ag). The second electrode 240 is thin so as to have light-transmissive (semi-transmissive) property.

In addition, an encapsulation layer or an encapsulation film 250 is disposed on the second electrode 244 in order to prevent or reduce outer moisture from penetrating into the light emitting diode D. For example, the encapsulation layer 250 can have, but is not limited to, a lamination structure of a first inorganic insulating layer 252, an organic insulating layer 254 and a second inorganic insulating layer 256.

For example, each of the first inorganic insulating layer 252 and the second inorganic insulating layer 256 can comprise, but is not limited to, an inorganic insulating material such as silicon oxide (SiOₓ, wherein 0<x≤2) or silicon nitride (SiNₓ, wherein 0<x≤2). For example, the organic insulating layer 254 can comprise, but is not limited to, an organic insulating material such as epoxy resin, photo-acryls and/or photosensitive acrylic polymer.

The organic insulating layer 254 is disposed between the first inorganic insulating layer 252 and the second inorganic insulating material 256. The organic insulating layer 254 makes a bottom steps flat and provides a flat surface.

A touch sensor 260 comprising a first touch electrode 266 and a second touch electrode 268 can be disposed on the encapsulation layer 250. For example, a connection electrode 262 can be disposed on the encapsulation layer 260, a first insulating material layer 264a with first and second contact holes exposing both sides of the connection electrode 262 can be disposed on the connection electrode 262, and the first touch electrode 266 and the second touch electrode 268 can be disposed on the first insulating material layer 264a.

The first touch electrodes 266 disposed adjacently can contact to the connection electrode 262 through the first and second contact holes to be connected electrically to each other. For example, the first insulating material layer 264a can comprise, but is not limited to, an inorganic insulating material such as silicon oxide (SiOₓ, wherein 0<x≤2) or silicon nitride (SiNₓ, wherein 0<x≤2).

A buffer layer can be disposed between the second inorganic insulating layer 256 of the encapsulation layer 250 and the first insulating material layer 264a. For example, the buffer layer can comprise, but is not limited to, an inorganic insulating material such as silicon oxide (SiOₓ, wherein 0<x≤2) or silicon nitride (SiNₓ, wherein 0<x≤2).

A second insulating material layer 264b can be disposed on the first touch electrode 266 and the second touch electrode 268. For example, the second insulating material layer 264b can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryls.

A black matrix 270 and a color filter layer 272 can be disposed on the second insulating material layer 264b. Alternatively, the touch sensor 260 comprising the connection electrode 262, the first insulating material layer 264a, the first touch electrode 266, the second touch electrode 268 and the second insulating material layer 264b can be omitted, and the black matrix 270 and the color filter layer 272 can be disposed on the encapsulation layer 250.

The black matrix 270 is disposed in a non-emission area NEA of an edge of the pixel region P, and has an opening corresponding to the light emitting diode D. For example, the black matrix 270 can comprise a light-shielding or light-absorbing material such as a black resin and/or carbon black.

The color filter layer 272 is disposed in the emission area EA corresponding to the opening of the black matrix. When the pixel region P comprises the red (R) pixel, the green (G) pixel and the blue (B) pixel, the color filter layer 272 can comprise a red color filter pattern corresponding to the red (R) pixel, a green color filter pattern corresponding to the green (G) pixel and a blue color filter pattern corresponding to the blue (B) pixel. The red color filter pattern can comprise at least one of a red dye and a red pigment, the green color filter pattern can comprise at least one of a green dye and a green pigment, and the blue color filter pattern can comprise at least one of a blue dye and a blue pigment.

A second passivation layer can be disposed on the second insulating material layer 264b, and the black matrix 270 and the color filter layer 272 can be disposed on the second passivation layer. The second passivation layer can comprise, but is not limited to, an inorganic insulating material such as silicon oxide (SiOₓ, wherein 0<x≤2) or silicon nitride (SiNₓ, wherein 0<x≤2).

A first insulating layer 280 can be disposed on the color filter layer 272 and the black matrix 270. For example, the first insulating layer 280 can comprise, but is not limited to, an organic insulating material such as epoxy resin and/or photo-acryls. Alternatively, a second insulating layer can be disposed on the first insulating layer 280.

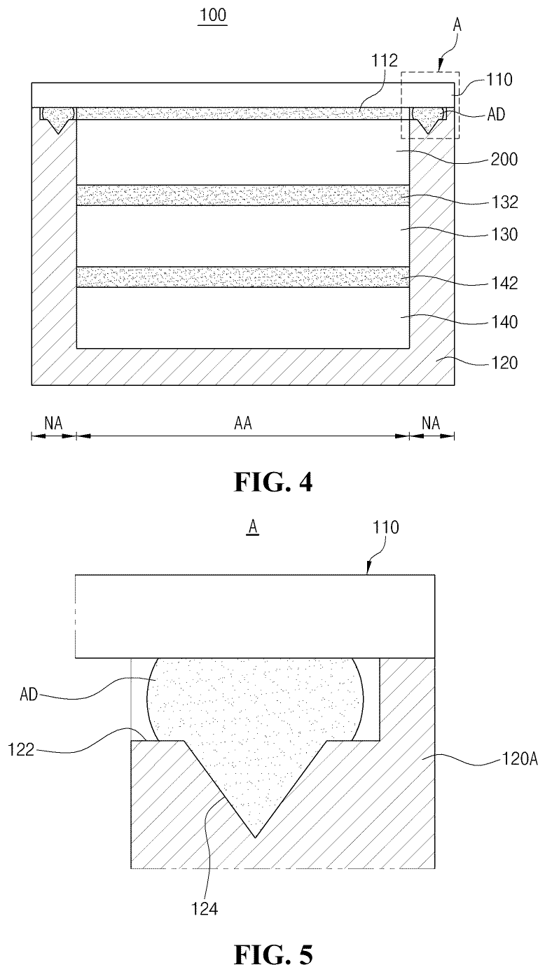

The display device fabricated by joining the cover window and the rear cover will be described in more detail. FIG. 4 illustrates a schematic cross-sectional view of a display device in accordance with various first embodiments of the present disclosure. FIG. 5 illustrates a cross-sectional view enlarging “A” portion in FIG. 4.

Referring to FIGS. 4 and 5, the cover window 110 is disposed on the display panel 200, and the heat dissipation sheet 130 and the core plate 140 are disposed in a display area AA of the rear surface of the display panel 200. The display area AA can comprise the emission area EA and the non-emission area NEA (FIG. 3). Among the rear cover 120 disposed on the rear surface of the core plate 140, the side surface 120A, which is an outer edge corresponding to a non-display area NA, extends upwardly to accommodate the display panel 200, the heat dissipation sheet 130 and the core plate 140.

An air gap can be formed between the cover window 110 and the display panel 200, between the display panel 200 and the heat dissipation sheet 130, and between the heat dissipation sheet 130 and the core plate 140. Alternatively, such members are connected to each other using engagement means such as adhesive and/or a foam tape.

For example, a first adhesive layer 112 between the rear surface of the cover window 110 and the upper surface of the display panel 200 can be located, a second adhesive layer 132 between the rear surface of the display panel 200 and the upper surface of the heat dissipation sheet 130 can be located, and a third adhesive layer 142 between the rear surface of the heat dissipation sheet 130 and the upper surface of the core plate 140. As an example, each of the first adhesive layer 112, the second adhesive layer 132 and the third adhesive layer 142 can comprise, but is not limited to, an optically clear adhesive (OCA) and/or a pressure sensitive adhesive (PSA).

Alternatively, the second adhesive layer 132 can be a foam tape disposed in the rear edge of the display panel 200 and in the upper edge of the heat dissipation sheet 130, and the third adhesive layer 142 can be a foam tape disposed in the rear edge of the heat dissipation sheet 130 and in the upper edge of the core plate 140, but is not limited thereto. In this case, an air gap can be located between the rear surface of the display panel 200 and the upper surface of the heat dissipation sheet 130, and between the rear surface of the heat dissipation sheet 130 and the upper surface of the core plate 140.

As the air gap between the display panel 200 and the heat dissipation sheet 130 exists, any shocks applied to the display panel 200 from the outside cannot be transferred to the heat dissipation sheet 130 and any shocks applied to the heat dissipation sheet 130 from the outside cannot be transferred to the display panel 200, and thereby, implementing the display device 100 with beneficial durability.

In another embodiment, at least one of the adhesive, a tape member and an adhesive sheet is interposed between the heat dissipation sheet 130 and the core plate 140 to locate the third adhesive layer 142. As an example, the third adhesive layer 142 can be located by applying the adhesive such as an epoxy-containing adhesive, an acrylate-containing adhesive and an urethane-containing adhesive in joining the heat dissipation sheet 130 and the core plate 140, or by laminating the adhesive on the rear surface of the heat dissipation sheet 130 or the upper surface of the core plate 140 in advance, and then processing those members.

A groove 124 of non-flat portion is positioned along the upper surface 122 of the rear cover 120, more specifically, the side 120A of the rear cover. The adhesive member AD is located between the groove 124 positioned along the upper surface 122 of the rear cover 120 and the rear edge of the cover window 110 corresponding to the non-display area NA. As the adhesive member AD is located or disposed between the upper surface 122 of the rear cover 120 and the rear edge of the cover window 110, it is possible to prevent moistures and impurities from entering into the display panel 200.

As the adhesive member AD is located between the upper surface 122 of the rear cover 120 disposed correspondingly to the non-display area NA of the outmost area of the display device 100 and the rear edge of the cover window 110, it is possible to enlarge the display area AA and to reduce the non-display area NA.

In addition, as the groove 124 of the non-flat portion is positioned along the upper surface 122 of the rear cover 120, an area where the adhesive member AD on the upper surface 122 of the rear cover 120 can be increased. Accordingly, the adhesive force between the upper surface of the rear cover 120 and the rear edge of the cover window 110 can be maximized. Since the adhesive member AD can maintain its adhesive force while a width W (FIG. 7) of the rear cover 120 reduces, it is possible to implement narrow bezel with a reduced width of a bezel corresponding to the non-display area NA.

The adhesive member AD can comprise any curable resins, for example, ultra-violet (UV) curable resins. For example, the adhesive member AD can comprise, but is not limited to, an acryl-containing resin, a (meth)acryl-containing resin, an epoxy-containing resin and/or a urethane-containing resin. The adhesive member AD can have, but is not limited to, a glue form discharged into the inside of the groove 124 using a nozzle.

In the present disclosure, the groove 124 positioned along the upper surface 122 of the rear cover 120 can have different shapes depending on an area of the rear cover 120. In this case, it is possible to prevent the adhesive member AD from overflowing to the outside of the groove 124 of the application area.

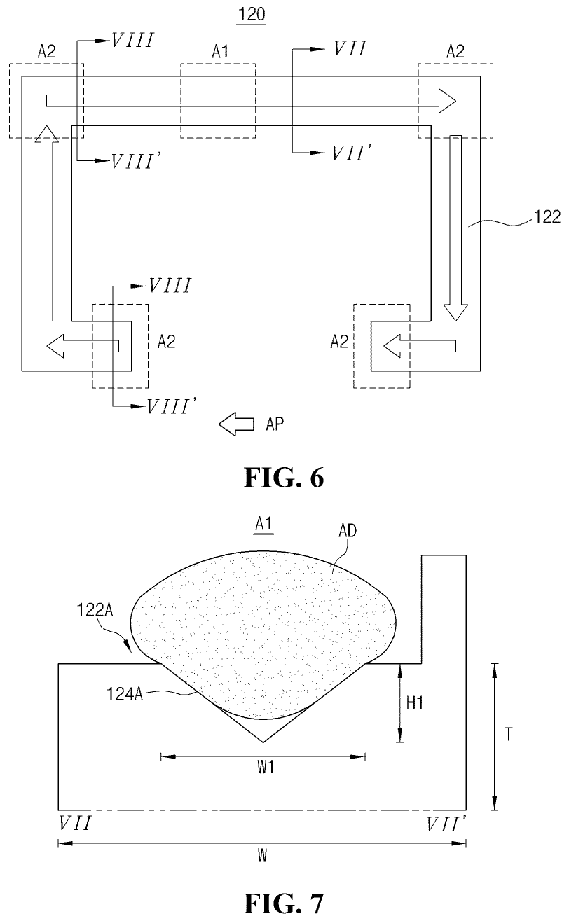

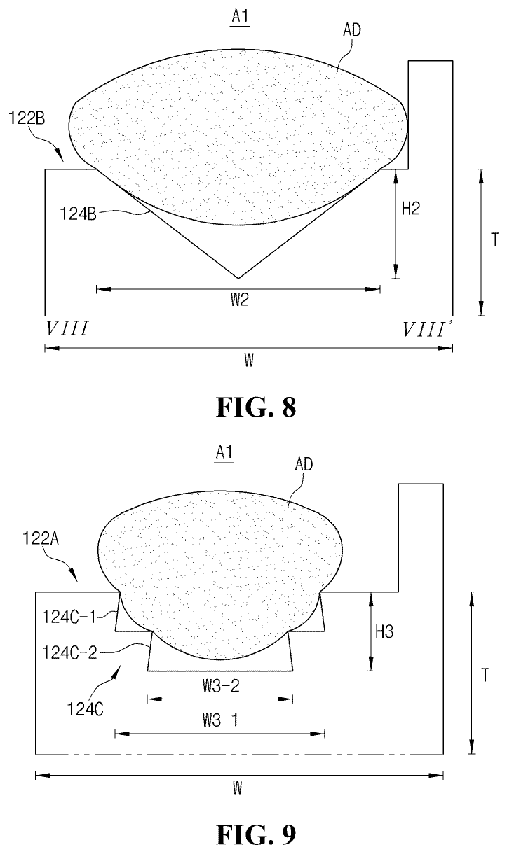

FIG. 6 illustrates a schematic plain view of a rear cover that can be applied to various embodiments of the present disclosure. FIG. 7 illustrates a schematic cross-sectional view of the rear cover taken along a line VII-VII″ in FIG. 6. FIG. 8 illustrates a schematic cross-sectional view of the rear cover taken along a line VIII-VIII′ in FIG. 6.

Referring to FIG. 6, an application path AP of the adhesive member AD can be positioned along the upper surface 122 of the rear cover 120. The rear cover 120 with a roughly rectangular plane shape can be divided into a first area A1 and a second area A2 depending on a region where the adhesive member AD is applied. As an example, the first area A1 can be a region where the adhesive member AD is applied linearly on the upper surface 122 of the rear cover 120. The second area A2 can be a region where an initial application area of the adhesive member AD to the upper surface 122 of the rear cover 120, a final application area of the adhesive member AD to the upper surface 122 of the rear cover 120, or a corner area of upper surface 122 of the rear cover 120.

In one embodiment, the rear cover 120 can have a plane shape that is a closed rectangular frame shape that completely surrounds the outside of the display panel 200, the heat dissipation sheet 130 and the core plate 140. In another embodiment, the rear cover 120 can have an open plane shape that exposes a portion of the outside of the display panel 200, the heat dissipation sheet 130 and the core plate 140.

Referring to FIGS. 7 and 8, both a first upper surface 122A of the rear cover 120 corresponding to the first area A1 and a second upper surface 122B of the rear cover 120 corresponding to the second area A2 has the same width W. However, grooves 124A and 124B having different sizes or dimensions protruding downwardly are positioned along the first upper surface 122A of the rear cover 120 corresponding to the first area A1 and the second upper surface 122B of the rear cover 120 corresponding to the second area A2, respectively. As an example, both the first groove 124A and the second groove 124B can have a concave-shaped cross-section. The first groove 124A with the concave-shaped cross-section positioned along the upper surface 122A of the rear cover 120 corresponding to the first area A1 has a shape different from a shape of the second groove 124B with the concave-shaped cross-section positioned along the upper surface 122B of the rear cover 120 corresponding to the second area A2.

A first width W1 and/or a first depth H1 of the first groove 124A with the concave-shaped cross-section positioned along the first upper surface 122A of the rear cover 120 corresponding to the first area A1 are different from a second width W2 and/or a second depth H2 of the second groove 124B with the concave-shaped cross-section positioned along the second upper surface 122B of the rear cover 120 corresponding to the second area A2.

For example, the first width W1 of the first groove 124A with the concave-shaped cross-section positioned along the first upper surface 122A of the rear cover 120 corresponding to the first area A1 can be smaller than the second width W2 of the second groove 124B with the concave-shaped cross-section positioned along the second upper surface 122B of the rear cover 120 corresponding to the second area A2. Alternatively, the first depth H1 of the first groove 124A with the concave-shaped cross-section positioned along the first upper surface 122A of the rear cover 120 corresponding to the first area A1 can be smaller than the second depth H2 of the second groove 124B with the concave-shaped cross-section positioned along the second upper surface 122B of the rear cover 120 corresponding to the second area A2.

In applying the adhesive member AD onto the upper surface 122 of the rear cover 120, the amount of the adhesive member AD discharged can increase due to the pressure at the initial point of application, and the adhesive member AD can be continuously discharged due to residual pressure even at the final point of the application. In addition, the application speed of the adhesive member AD in the corner area of the rear cover 120 can be different from the application speed of the adhesive member AD in the first area A1 of the rear cover 120.

Accordingly, compared to the first width W1 and/or the first depth H1 of the first groove 124A of the concave-shaped cross-section positioned along the first upper surface 122A of the rear cover 120 corresponding to the first area A1, the second width W2 and/or the second depth H2 of the second groove 124B of the concave-shaped cross-section positioned along the second upper surface 122B of the rear cover 120 corresponding to the second area A2 is designed to be larger, and thereby, preventing the adhesive member AD from overflowing to the outside of the second groove 124B in the second area A2.

On the contrary, when the first width W1 and/or the first depth H1 of the first groove 124A of the concave-shaped cross-section positioned along the first upper surface 122A of the rear cover 120 corresponding to the first area A1 is set to be the same as the second width W2 and/or the second depth H2 of the second groove 124B of the concave-shaped cross-section positioned along the second upper surface 122B of the rear cover 120, the adhesive member AD in the first area A1 cannot be sufficiently applied to the first groove 124A. In this case, sufficient adhesive force may not be secured between the rear cover 120 and the cover window 110 corresponding to the first area A1.

For example, the first width W1 of the first groove 124A of the concave-shaped cross-section positioned along the first upper surface 122A of the rear cover 120 corresponding to the first area A1 can be, but is not limited to, about 35% to about 65%, for example, about 40% to about 60%, of the width W of the rear cover 120. The first depth H1 of the first groove 124A of the concave-shaped cross-section positioned along the first upper surface 122A of the rear cover 120 corresponding to the first area A1 can be, but is not limited to, about 35% to about 65%, for example, about 40% to about 60%, of the thickness T of the rear cover 120.

Alternatively, the second width W2 of the second groove 124B of the concave-shaped cross-section positioned along the second upper surface 122B of the rear cover 120 corresponding to the second area A2 can be, but is not limited to, about 65% to about 90%, for example, about 65% to about 80%, of the width W of the rear cover 120. The second depth H2 of the second groove 124B of the concave-shaped cross-section positioned along the second upper surface 122B of the rear cover 120 corresponding to the second area A2 can be, but is not limited to, about 65% to about 90%, for example, about 65% to about 80%, of the thickness T of the rear cover 120.

In FIGS. 7 and 8, both the first groove 124A of the concave-shaped cross-section formed on the first upper surface 122A of the rear cover 120 corresponding to the first area A1 and the second groove 124B of the concave-shaped cross-section formed on the second upper surface 122B of the rear cover 120 corresponding to the second area A2 has a rough V-type cross-section. Alternatively, the first groove 124A and the second groove 124B of the concave-shaped cross-section can have other shapes such as U-type cross-section.

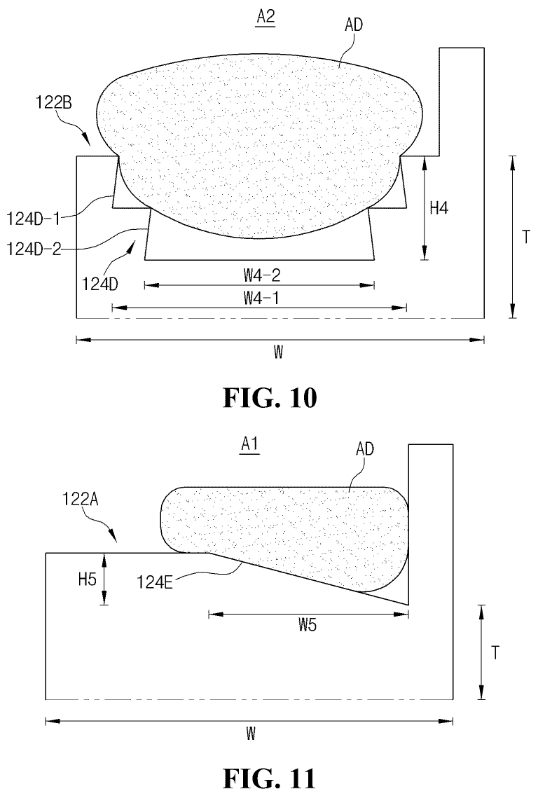

In FIGS. 7 and 8, the first groove 124A and the second groove 124B positioned along the upper surface 122A or 122B of the rear cover 120 has one concave shape. Alternatively, the grooves on the rear cover 120 can have a cross-section with plural concave shapes. FIGS. 9 and 10 illustrate a schematic cross-sectional view of a rear cover that can be applied to another embodiment of the present disclosure.

Referring to FIGS. 9 and 10, a first groove 124C and a second groove 124D with a dual concave-shaped cross-section are positioned along the first surface 122A of the rear cover 120 corresponding to the first area A1, and the second surface 122B of the rear cover 120 corresponding to the second area A2, respectively.

The first groove 124C of the dual concave-shaped cross-section can comprise a first concave portion 124C-1 positioned along the first upper surface 122A of the rear cover 120 corresponding to the first area A1, and a second concave portion 124C-2 positioned under the first concave portion 124C-1. The first concave portion 124C-1 can have a first-first width W3-1 and a first-first depth H3-1, and the second concave portion 124C-2 can have a first-second with W3-2 and a first-second depth H3-2. The first-first width W3-1 and/or the first-first depth H3-1 of the first concave portion 124C-1 can be larger than the first-second width W3-2 and/or the first-second depth H3-2 of the second concave portion 124C-2.

The second groove 124D of the dual concave-shaped cross-section can comprise a first concave portion 124D-1 positioned along the second upper surface 122B of the rear cover 120 corresponding to the second area A2, and a second concave portion 124D-2 positioned under the first concave portion 124D-1. The first concave portion 124D-1 can have a second-first width W4-1 and a second-first depth H4-1, and the second concave portion 124D-2 can have a second-second with W4-2 and a second-second depth H4-2. The second-first width W4-1 and/or the second-first depth H4-1 of the first concave portion 124D-1 can be larger than the second-second width W4-2 and/or the second-second depth H4-2 of the second concave portion 124D-2.

The first-first width W3-1 and/or the first-first depth H3-1 of the first concave portion 124C-1 of a portion of the first groove 124C with the dual concave-shaped cross-section positioned along the first upper surface 122A of the rear cover 120 corresponding to the first area A1 can be smaller than the second-first width W4-1 and/or the second-first depth H4-1 of the first concave portion 124D-1 of a portion of the second groove 124D with the dual concave-shaped cross-section positioned along the second upper surface 122B of the rear cover 120 corresponding to the second area A2. The first-second width W3-2 and/or the first-second depth H3-2 of the second concave portion 124C-2 of a portion of the first groove 124C with the dual concave-shaped cross-section positioned along the first upper surface 122A of the rear cover 120 corresponding to the first area A1 can be smaller than the second-second width W4-2 and/or the second-second depth H4-2 of the second concave portion 124D-2 of a portion of the second groove 124D with the dual concave-shaped cross-section positioned along the second upper surface 122B of the rear cover 120 corresponding to the second area A2.

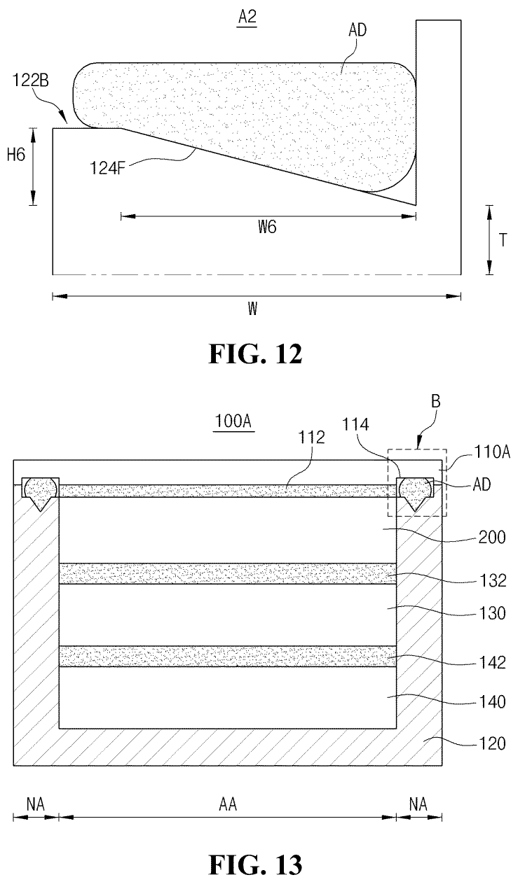

Referring to FIGS. 7 to 10, the grooves 124A, 124B, 124C and 124D positioned along the upper surface of the rear cover 120 have the concave-shaped cross-section. Alternatively, the groove can have a sloping portion or a sloping cross-section of a non-flat portion. FIGS. 11 and 12 illustrate a schematic cross-sectional view of a rear cover that can be applied to another embodiment of the present disclosure.

Referring to FIGS. 11 and 12, a first groove 124E and a second groove 124F with a downward sloping cross-section are positioned along the first upper surface 122A of the rear cover 120 corresponding to the first area A1 and the second upper surface 122B of the rear cover 120 corresponding to the second area A2, respectively.

The first groove 124E of the sloping cross-section positioned along the first upper surface 122A of the rear cover 120 corresponding to the first area A1 can have a first-third width W5 and a first-third depth H5. The second groove 124F of the sloping cross-section positioned along the second upper surface 122B of the rear cover 120 corresponding to the second area A2 can have a second-third width W6 and a second-third depth H6. The first-third width W5 of the first groove 124E can be smaller than the second-third width W6 of the second groove 124F. The first-third depth H5 of the first groove 124E can be smaller than the second-third depth H6 of the second groove 124F.

For example, the first-third width W5 of the first groove 124E of the sloping cross-section positioned along the first upper surface 122A of the rear cover 120 corresponding to the first area A1 can be, but is not limited to, about 35% to about 65%, for example, about 40% to about 60%, of the width W of the rear cover 120. The first-third depth H5 of the first groove 124E of the sloping cross-section positioned along the first upper surface 122A of the rear cover 120 corresponding to the first area A1 can be, but is not limited to, about 35% to about 65%, for example, about 40% to about 60%, of the thickness T of the rear cover 120.

Alternatively, the second-third width W6 of the second groove 124F of the sloping cross-section positioned along the second upper surface 122B of the rear cover 120 corresponding to the second area A2 can be, but is not limited to, about 65% to about 90%, for example, about 65% to about 80%, of the width W of the rear cover 120. The second-third depth H6 of the second groove 124B of the sloping cross-section positioned along the second upper surface 122B of the rear cover 120 corresponding to the second area A2 can be, but is not limited to, about 65% to about 90%, for example, about 65% to about 80%, of the thickness T of the rear cover 120.

In accordance with the first embodiment of the present disclosure, the grooves 124, 124A, 124B, 124C, 124D, 124E and 124F of the non-flat portion are positioned along the upper surface 122, 122A or 122B of the rear cover 120 joined to the rear edge of the cover window 100 disposed on the display panel 200 so that the adhesive force between the cover window 110 and the rear cover 120 can be maximized. The grooves 124A, 124B, 124C, 124D, 124E and 124F with different shapes and/or configurations depending on the areas A1 and A2 of the rear cover 120 are positioned, and therefore, it is possible to prevent the adhesive member AD from overflowing those grooves 124A, 124B, 124C, 124D, 124E and 124F.

In the above first embodiments, the grooves 124, 124A, 124B, 124C, 124D, 124E and 124F with different shapes depending on the upper surfaces 122, 122A and 122B of the rear cover 120 are positioned. Cover window can further comprise a structure in which the adhesive member can be introduced in the rear edge thereof so as to improve the adhesive force between the cover window and the rear cover.

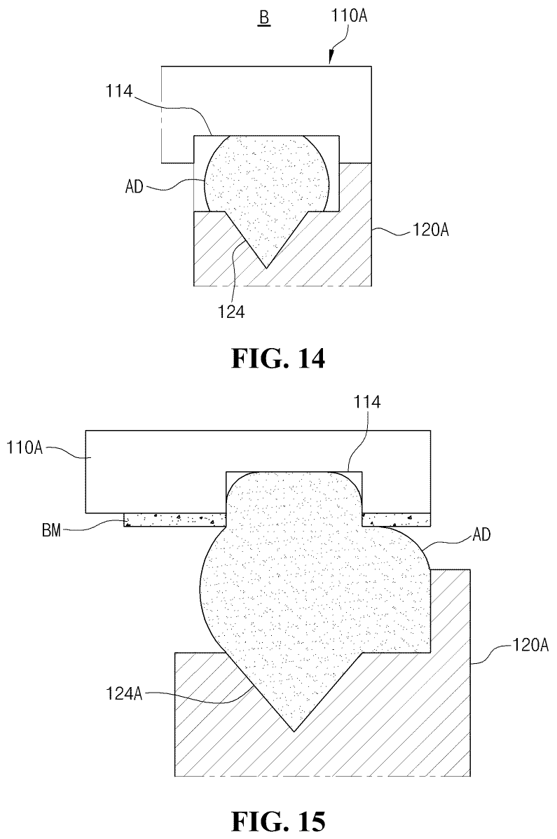

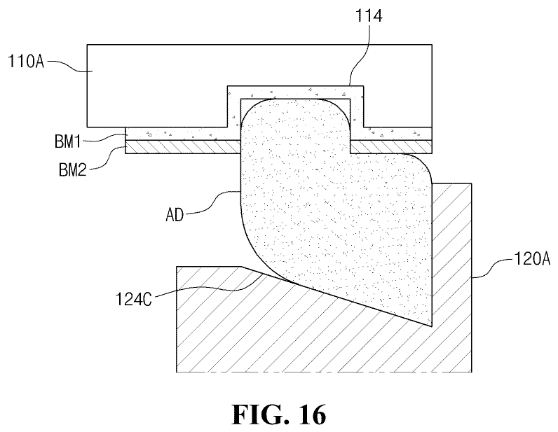

FIG. 13 illustrates a schematic cross-section view of a display device in accordance with a second embodiment of the present disclosure. FIG. 14 illustrates a cross-sectional view enlarging “B” portion in FIG. 13. FIG. 15 is a schematic cross-sectional view where adhesive material is applied or positioned between the rear cover and the cover window in the display device in accordance with the second embodiment of the present disclosure. FIG. 16 is a schematic cross-section view where adhesive material is applied or positioned between the rear cover and the cover window in the display device in accordance with a third embodiment of the present disclosure.

Referring to FIGS. 13 and 14, the display device 100A in accordance with the second embodiment of the present disclosure comprise a display panel 200, a cover window 110A disposed on the display panel 200, a rear cover 120 disposed under the display panel 200, and a heat dissipation sheet 130 and a core plate 140 disposed sequentially between the display panel 200 and the rear cover 120. A first adhesive layer 112 can be disposed between the cover window 110A and the display panel 200, a second adhesive layer 132 can be disposed between the display panel 200 and the heat dissipation sheet 130, and a third adhesive layer 142 can be disposed between the heat dissipation sheet 130 and the core plate 140.

The side surface 120A of the rear cover 120 is extended upward outside of the display panel 200, the heat dissipation sheet 130 and the core plate 140. A groove 124 of the non-flat portion is positioned along the upper surface 122 of the rear cover 120. The groove 124 can have various different shapes depending on the areas of the rear cover as described in the first embodiment.

Referring to FIGS. 6 to 12, the groove 124 can have the first grooves 124A, 124C and 124E positioned along the first upper surface 122A of the rear cover 120 corresponding to the first area A1, and the second grooves 124B, 124D and 124F positioned along the second upper surface 122B of the rear cover 120 corresponding to the second area A2.

In the display device 100A in accordance with the second embodiment of the present disclosure, the cover window 110A further comprises a receiving groove 114 with a cross-sectional shape protruding toward an upper surface of the cover window 110A in the rear edge of the cover window 110A joined to the upper surface 122 of the cover window 110A. The adhesive member AD applied to the groove 124 positioned along the upper surface 122 of the rear cover 120 can be inserted into the receiving groove 114 positioned or formed on the rear edge of the cover window 110A. In this case, the adhesive force between the cover window 110A and the rear cover 120 can be further improved.

Referring to FIGS. 4, 13 and 15, the black matrix BM can be disposed between the cover window 110A and the display panel 200 corresponding to the non-emission area NEA. The black matrix BM can be disposed between the rear edge of the cover window 110A adjacent to the receiving groove 114 and the display panel 220, but is not disposed within the receiving groove 114. As an example, the black matrix BM can be disposed on the rear surface of the cover window 110A corresponding to the inner area of the receiving groove 114 and/or the outer area of the receiving groove 114.

The adhesive member AD inserted into the receiving groove 114 can comprise a light-shielding material. As an example, the adhesive member AD can comprise colorant such as a black dye and/or a black pigment. In this case, the adhesive member AD inserted into the receiving groove 114 can block or absorb light as the black matrix BM.

Referring to FIGS. 4, 13 and 16, a first black matrix BM1 and a second black matrix BM2 can be disposed sequentially between the cover window 110A and the display panel 200 corresponding to the non-emission area NEA. Plural black matrixes BM1 and BM2 are disposed between the cover window 110A and the display panel 200 so that the light can be blocked efficiently.

The first black matrix BM1 can be disposed on the entire rear edge including the receiving groove 114 of the cover window 110A. The second black matrix BM2 can be disposed between the rear surface of the cover window 110A adjacent to the receiving groove 114 and the display panel, but the second black matrix BM2 is not disposed within the receiving groove 114. As an example, the second black matrix BM2 can be disposed on the rear surface of the cover window 110A corresponding to the inner area of the receiving groove 114 and/or the outer area of the receiving groove 114. The adhesive member AD inserted into the receiving groove 114 can comprise a light-shielding material. The adhesive member AD inserted into the receiving groove 114 can block or absorb the light as the first black matrix BM1.

In accordance with the present disclosure, the grooves 124, 124A, 124B, 124C, 124D, 124E and 124F with different shapes depending upon the areas of the upper surfaces 122, 122A and 122B of the rear cover 120 joined to the rear edge of the cover window 110 or 110A. The adhesive force of the adhesive member AD between the cover window 110 or 110A, and the rear cover 120 can be further increased. While the width W of the rear cover 120 decreases, it is possible to secure beneficial adhesive force between the cover window 110 or 110A and the rear cover 120. In the display device 100 or 100A, the bezel area corresponding to the non-display area NA decreases significantly, and therefore, it is possible to implement narrow bezel.

In addition, the receiving groove 112 into which the adhesive member AD can be introduced is configured along the rear edge of the cover window 110A. The adhesive force between the cover window 110A and the rear cover 120 is improved. It is possible to fabricate the display device 110A with stable modularization and with beneficial durability.

[Example] Evaluation of Repulsive Force Between Rear Cover with V-Shaped Cross-Sectional Concave Portion and Cover Window.

In a comparative example where a groove was not positioned the upper surface of the linear region (A1 area in FIG. 6) of the rear cover corresponding to the rear edge of the cover window, and in an example where the groove with a V-shaped cross-sectional shape was positioned along the upper surface of the linear region of the rear cover, the repulsive force was simulated and evaluated. The adhesive force was evaluated by evaluating the repulsive force of the adhesive when a tensile force occurs at the center of the cover window.

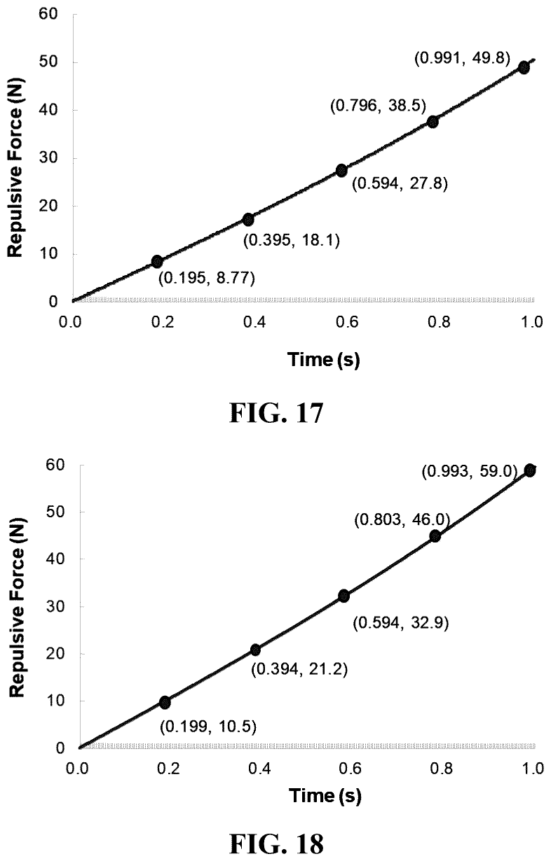

Referring to FIG. 7, the width W of the groove 124A positioned along the upper surface of the rear cover was designed to be 1.0 mm, the depth H1 of the groove 124A was designed to be 0.7 mm, and the thickness of the adhesive was designed to be 0.7 mm, and then the repulsive force of the adhesive was evaluated. In addition a peeling test of the adhesive was performed. The simulation results of the repulsive force evaluation are shown in the following Table 1 and the simulation results of the peeling test is shown in FIGS. 17 and 18. In Table 1, the displacement indicates a displacement in the upper direction of the cover window based on the cross-section. In FIGS. 17 and 18, the X-axis represents elapsed time, and Y-axis represents the magnitude of the repulsive force.

TABLE 1
Repulsive Force (Adhesive Force)

| | Displacement | Repulsive Force (N) | | Force |
|---|---|---|---|---|
| Sample | (nm) | Comparative Example | Example | Increase |
| 1 | 0.19 | 8.77 | 10.5 | 120% |
| 2 | 0.39 | 18.1 | 21.2 | 117% |
| 3 | 0.59 | 27.8 | 32.9 | 118% |
| 4 | 0.79 | 38.5 | 46 | 119% |
| 5 | 0.99 | 49.8 | 59 | 118% |

Referring to Table 1 and FIGS. 17-18, as the groove with the concave-shaped cross-section is positioned on the upper surface of the rear cover corresponding to the rear edge of the cover window, the repulsive force with relating to the adhesive force between the cover window and the rear cover increase significantly. In addition, the groove on the upper surface of the rear cover can increase the adhesive intensity of the adhesive.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A display device, comprising:
a display panel disposed in a display area on a substrate;
a cover window disposed on the display panel; and
a rear cover disposed on a rear surface of the display panel and in a non-display area outside of the display panel to accommodate the display panel,
wherein an upper surface of the rear cover disposed outside of the display panel is joined along a rear edge of the cover window corresponding to the non-display area,
wherein at least one groove onto which an adhesive material is applied is positioned along the upper surface of the rear cover,
wherein the at least one groove comprises:
a first groove positioned in a first area of the upper surface of the rear cover; and
a second groove positioned in a second area of the upper surface of the rear cover, and
wherein the first groove has a shape different from a shape of the second groove.

2. The display device of claim 1, wherein the at least one groove positioned along the upper surface of the rear cover has a downward protruding cross section.

3. The display device of claim 1, wherein the at least one groove positioned along the upper surface of the rear cover has a wedge-shaped cross section.

4. The display device of claim 1, wherein the at least one groove positioned along the upper surface of the rear cover comprises:
a first concave portion positioned on the upper surface of the rear cover; and
a second concave portion positioned under the first concave portion.

5. The display device of claim 4, wherein the first concave portion has a width larger than a width of the second concave portion.

6. The display device of claim 1, wherein the at least one groove positioned along the upper surface of the rear cover has a downward sloping cross section.

7. The display device of claim 1, wherein the first area of the upper surface of the rear cover is an area where the adhesive material is linearly applied to the upper surface of the rear cover, and
wherein the second area of the upper surface of the rear cover is an initial application area of the adhesive material to the upper surface of the rear cover, a final application area of the adhesive material to the upper surface of the rear cover, or a corner area of the upper surface of the rear cover.

8. The display device of claim 1, wherein the first groove has a width different from a width of the second groove.

9. The display device of claim 1, wherein the first groove has a width smaller than a width of the second groove.

10. The display device of claim 1, wherein the first groove has a depth different from a depth of the second groove.

11. The display device of claim 1, wherein the first groove has a depth smaller than a depth of the second groove.

12. The display device of claim 1, wherein the display device further comprises a receiving groove having a cross-sectional shape protruding toward an upper surface of the cover window on a rear edge of the cover window corresponding to the upper surface of the rear cover.

13. The display device of claim 12, wherein the display device further comprises a black matrix disposed between the display panel and the cover window.

14. The display device of claim 13, wherein the black matrix is disposed between the rear surface of the cover window adjacent to the receiving groove and the display panel.

15. The display device of claim 13, wherein the black matrix comprises:
a first black matrix disposed between the display panel and the cover window; and
a second black matrix disposed between the first black matrix and the display panel.

16. The display device of claim 15, wherein the first black matrix is disposed between the rear surface of the cover window including the receiving groove and the display panel, and
wherein the second black matrix is disposed between the rear surface of the cover window adjacent to the receiving groove and the display panel.

17. The display device of claim 13, wherein the adhesive material comprises a light shielding material.

18. The display device of claim 1, wherein the display panel further comprises:
a light emitting diode disposed on the substrate; and
a thin film transistor disposed between the substrate and the light emitting diode.

19. The display device of claim 18, wherein the light emitting diode comprises an organic light emitting diode.

20. The display device of claim 1, wherein the display panel further comprises a heat dissipation sheet and a core plate sequentially disposed between the display panel and the rear cover.
